(19) United States
(12) Patent Application Publication
(10) Pub. No.: US 2024/0071732 A1
(43) Pub. Date: Feb. 29, 2024

(54) EDGE RING, DRY ETCHING APPARATUS HAVING THE SAME, AND OPERATION METHOD OF ETCHING APPARATUS

(71) Applicant: SAMSUNG ELECTRONICS CO.,LTD., Suwon-si (KR)

(72) Inventors: Hyun-Sik HWANG, Suwon-si (KR); Jinyoung BANG, Suwon-si (KR); Sungil CHO, Suwon-si (KR); Junghwan UM, Suwon-si (KR)

(73) Assignee: SAMSUNG ELECTRONICS CO., LTD., Suwon-si (KR)

(21) Appl. No.: 18/236,748

(22) Filed: Aug. 22, 2023

(30) Foreign Application Priority Data
Aug. 24, 2022 (KR) 10-2022-0106347

(51) Int. Cl. H01J 37/32; H01L 21/3065; H01L 21/311

(52) U.S. Cl. CPC H01J 37/32642; H01J 37/32449; H01J 37/32724; H01L 21/3065; H01L 21/31116; H01L 21/31144; H01J 2237/334

(57) ABSTRACT

A dry etching apparatus includes a process chamber; a support provided in the process chamber and configured to support a substrate; a gas supply configured to supply a process gas including a hydrogen gas (H2) and a fluorocarbon gas (CxFy) into the process chamber; a plasma source configured to generate plasma using the process gas in the process chamber, wherein the support includes: an electrostatic chuck on which the substrate is disposed; an edge ring provided along a circumference of the electrostatic chuck and supporting an edge region of the substrate; an adhesive gel pad provided between the electrostatic chuck and the edge ring; and a coating layer formed only on a surface of the edge ring, which is exposed to the plasma.

### CROSS-REFERENCE TO RELATED APPLICATION

This application is based on and claims priority under 35 U.S.C. § 119 to Korean Patent Application No. 10-2022-0106347, filed on Aug. 24, 2022, in the Korean Intellectual Property Office, the disclosure of which is incorporated by reference herein in its entirety.

### BACKGROUND

The present disclosure relates to an edge ring, a dry etching apparatus having an edge ring, and an operation method of an etching apparatus, and more particularly, to an edge ring for preventing the upper portion of the edge ring from being damaged by plasma, a dry etching apparatus including an edge ring for preventing the upper portion of the edge ring from being damaged by plasma, and an operation method of the etching apparatus.

In a semiconductor device manufacturing process, an etching process of etching a film on a semiconductor substrate in a predetermined pattern is needed. Such an etching process includes a dry etching process and a wet etching process, and the plasma etching process is a type of the dry etching process. The plasma etching process has a feature of etching a film on a semiconductor substrate using plasma generated by spraying process gas into the process chamber through a shower head in a dry etching apparatus. However, there may be a problem that the upper portion of the edge ring is damaged by plasma.

### SUMMARY

One or more example embodiments provide a dry etching apparatus for preventing an upper portion of an edge ring from being damaged by plasma, and a method of operating the etching apparatus.

The present disclosure is not limited to what is mentioned above and will be clearly understood by those skilled in the art from the descriptions below.

According to an aspect of an example embodiment, a dry etching apparatus includes: a process chamber; a support provided in the process chamber and configured to support a substrate; a gas supply configured to supply a process gas including a hydrogen gas (H2) and a fluorocarbon gas (CxFy) into the process chamber; a plasma source configured to generate plasma using the process gas in the process chamber, wherein the support includes: an electrostatic chuck on which the substrate is disposed; an edge ring provided along a circumference of the electrostatic chuck and supporting an edge region of the substrate; an adhesive gel pad provided between the electrostatic chuck and the edge ring; and a coating layer formed only on a surface of the edge ring, which is exposed to the plasma.

According to an aspect of an example embodiment, a dry etching apparatus includes: a process chamber; a support configured to support a substrate in the process chamber; a gas supply configured to supply a process gas including a hydrogen gas (H2) and a fluorocarbon gas (CxFy) into the process chamber; and a plasma source configured to generate plasma using the process gas in the process chamber, wherein the support includes: an electrostatic chuck on which the substrate is disposed; an edge ring provided along a circumference of the electrostatic chuck and supporting an edge region of the substrate; an adhesive gel pad between the electrostatic chuck and the edge ring, and wherein the edge ring includes: a lower ring attached to the electrostatic chuck and configured to not be exposed to the plasma; and an upper ring provided on the lower ring and is configured to be exposed to the plasma.

According to an aspect of an example embodiment, an edge ring includes: an annular body configured to be used in dry etching equipment where an etching process is performed in a low-temperature environment, the annular body having a lower surface and an upper surface facing the lower surface; a thermally conductive adhesive gel pad adhered to the lower surface of the annular body; and a coating layer provided on the upper surface of the annular body, and the coating layer including a material having etching resistance to a hydrogen gas (H2) and a fluorocarbon gas (CxFy).

According to an aspect of an example embodiment, a method of operating an etching apparatus, includes: forming, on a substrate, a film to be etched; positioning the substrate on an electrostatic chuck of a support in a process chamber; supporting an edge region of the substrate with an edge ring of the support, the edge ring being provided along a circumference of the electrostatic chuck; positioning an adhesive gel pad between the electrostatic chuck and the edge ring; forming a coating layer having a thickness of about 100 nm to about 1 mm on only a surface of the edge ring; dry-etching the film on the substrate by generating plasma using a process gas in the process chamber, wherein the surface of the edge ring is exposed to the generated plasma; and moving the substrate to an outside of the process chamber.

### BRIEF DESCRIPTION OF THE DRAWINGS

The above and other aspects and features will be more apparent from the following description of example embodiments taken in conjunction with the accompanying drawings in which:

FIG. 1 is a schematic view of a dry etching apparatus according to one or more example embodiments;

FIG. 2 is an enlarged cross-sectional view showing an enlarged support unit of FIG. 1, according to one or more example embodiments.

FIG. 3 is an enlarged cross-sectional view showing an enlarged region III of FIG. 3, according to one or more example embodiments;

FIGS. 4 and 5 are cross-sectional views each illustrating a portion of a dry etching apparatus according to one or more example embodiments;

FIG. 6 is a schematic diagram of a cooling device included in a dry etching apparatus according to one or more example embodiments;

FIG. 7 is a graph illustrating a relative etch rate according to materials in a dry etching apparatus according to one or more example embodiments;

FIG. 8 is a perspective view of an edge ring included in a dry etching apparatus according to one or more example embodiments;

FIG. 9 is a cross-sectional view illustrating a process in which the edge ring of FIG. 8 is attached to an electrostatic chuck according to one or more example embodiments;

FIG. 10 is a flowchart illustrating a pattern forming process of a semiconductor device using a dry etching apparatus according to one or more example embodiments; and

FIGS. 11, 12, 13, 14 and 15 are cross-sectional views shown at each process sequence of the pattern forming process of the semiconductor device of FIG. 10, according to one or more example embodiments.

### DETAILED DESCRIPTION

Hereinafter, example embodiments will be described with reference to the attached drawings. The same reference numerals may be used for the same components in the drawings, and duplicate descriptions thereof may be omitted.

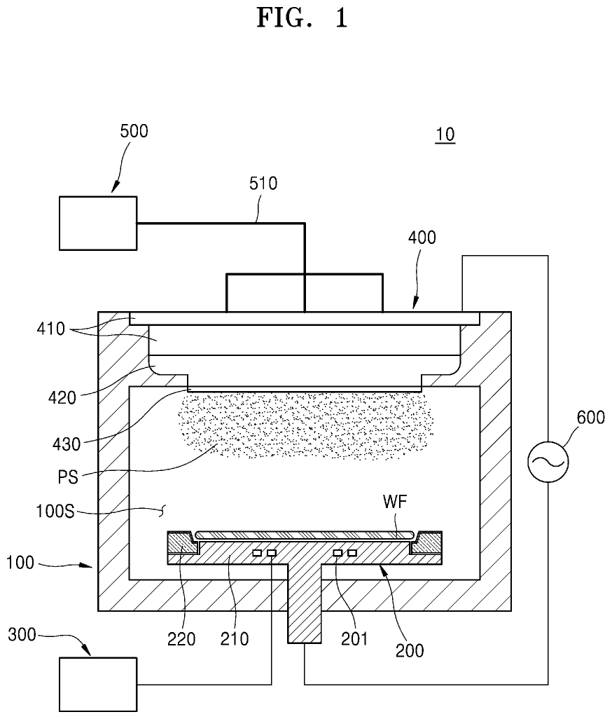

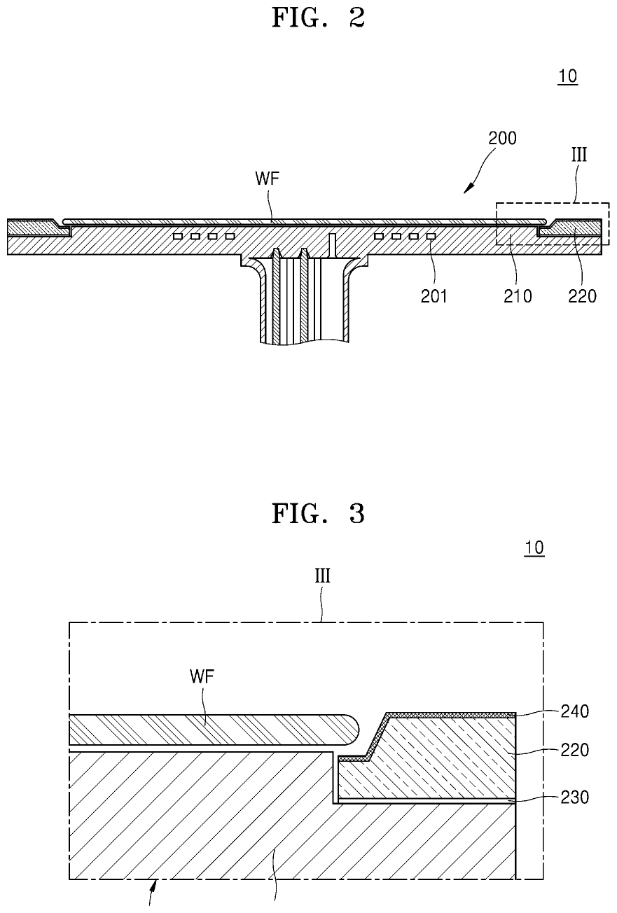

FIG. 1 is a schematic view of a dry etching apparatus according to one or more example embodiments, FIG. 2 is an enlarged cross-sectional view showing an enlarged support unit of FIG. 1, according to one or more example embodiments, and FIG. 3 is an enlarged cross-sectional view showing an enlarged region III of FIG. 3, according to one or more example embodiments.

Referring to FIGS. 1, 2 and 3, a dry etching apparatus 10 may include a process chamber 100 in which an etching process is performed, a support unit 200 supporting a substrate WF, a cooling unit (or cooling device) 300 cooling the support unit 200, a gas supply unit 400 supplying a process gas, a gas supply source 500 and a power supply unit 600.

The process chamber 100 may have an inner space 100S of a predetermined size, and may include, but is not limited to, a material having excellent wear resistance and corrosion resistance. The process chamber 100 may be referred to as a chamber housing. The process chamber 100 may include, but is not limited to, for example, an aluminum block. The process chamber 100 may maintain the inner space 100S in a sealed or vacuum state during a plasma treatment process (e.g., a dry etching process using plasma). The process chamber 100 may be a part of the dry etching apparatus 10, which includes a plurality of chambers.

The support unit 200 may be under the inner space 100S of the process chamber 100. The support unit 200 may include a cooling channel 201, an electrostatic chuck 210, and an edge ring 220. A substrate WF to be processed may be arranged on at least one of a top surface of the electrostatic chuck 210 and a top surface of the edge ring 220.

The support unit 200 may fix and support the substrate WF during the etching process. The support unit 200 may be formed of a combination of a conductive material and an insulating material, and may include, but is not limited to, a conductive portion capable of receiving an electrostatic force from an electrostatic force source, and a polar concavo-convex protrusion.

When an electrostatic force is applied between the substrate WF and the electrostatic chuck 210 using the bipolar electrostatic force supplied from the electrostatic force source, the substrate WF may be stably fixed to the electrostatic chuck 210 during the etching process. The concavo-convex protrusion may be on the electrostatic chuck 210 and may fix the substrate WF using bipolar electrostatic force. However, the support unit 200 is not limited to this method, and for example, the support unit 200 may fix the substrate WF using various schemes, including, but is not limited to, a vacuum adsorption scheme or a mechanical clamping scheme.

The substrate WF to be processed may be positioned a predetermined distance apart from the edge ring 220. This predetermined distance may be a characteristic determined according to the type of the semiconductor device being formed on the substrate WF. In one or more example embodiments, the edge ring 220 may include, but is not limited to, an insulating material. For example, the edge ring 220 may include a ceramic material, but not limited thereto. By way of further example, the edge ring 220 may include, but is not limited to, one selected from among silicon, silicon carbide, silicon nitride, silicon oxide, and aluminum oxide.

An adhesive gel pad 230 may be positioned between the electrostatic chuck 210 and the edge ring 220. That is, in the dry etching apparatus 10, the electrostatic chuck 210 and the edge ring 220 may be bonded to each other using the adhesive gel pad 230 and without using a fastening member such as a bolt. The adhesive gel pad 230 may include, but is not limited to, a material having adhesive properties and thermal conductivity. Detailed features of the edge ring 220 will be described below according to one or more example embodiments.

The cooling unit 300 may be configured to cool the support unit 200. The cooling unit 300 may supply a cooling fluid to the cooling channel 201 of the support unit 200. The cooling channel 201 of the support unit 200 is a passage through which the cooling fluid may flow, and may have a concentrical or helical pipe shape on the central axis of the support unit 200. The cooling unit 300 may be configured to adjust the temperature, flow rate, etc. of the cooling fluid supplied to the cooling channel 201 of the support unit 200 and thereby control the temperature of the support unit 200 and the temperature of the substrate WF on the support unit 200.

The cooling unit 300 may control and maintain the substrate WF on the support unit 200 at a low or cryogenic temperature during the plasma etching process. For example, the cooling unit 300 may cool the substrate WF to a predetermined temperature selected between about 0° C. and about −100° C. In such a low temperature or cryogenic environment, a plasma etching process may be performed on the substrate WF to form a high aspect ratio pattern on the substrate WF.

The gas supply unit 400 may sequentially include a gas introduction unit 410, a gas distribution plate 420, and a shower head 430. The gas supply unit 400 may be positioned apart from the support unit 200 by a predetermined interval at a position where the gas supply unit 400 faces the support unit 200 and is arranged on the process chamber 100. The gas supply unit 400 may supply the process gas to the inner space 100S through a gas supply pipe 510.

The gas supply source 500 may be connected to the gas supply unit 400 through the gas supply pipe 510. The gas supply pipe 510 may include a valve for supplying a process gas from the gas supply source 500 to the gas supply unit 400 and for switching a gas flow. The process gas may include, but is not limited to, for example, a fluorocarbon gas (CₓF_{y}), a hydrogen gas (H₂), or an inert gas.

The gas supply source 500 may be controlled by a gas controller. That is, by controlling the gas supply source 500, the gas controller may control the type of gas supplied to the gas supply unit 400, the start point and end point of the gas supply, the flow rate of the gas, and the like.

The power supply unit 600 is connected to the gas supply unit 400 (according to one or more example embodiments the power supply unit 600 serves as an upper electrode) and the support unit 200 (according to one or more example embodiments the support unit 200 serves as a lower electrode), and plasma PS may be generated in an inner space 100S between the gas supply unit 400 and the support unit 200 by using the power supplied from the power supply unit 600.

For example, the power supply unit 600 may apply high-frequency power of about 60 MHz to the gas supply unit 400 and may apply high-frequency power of about 2 MHz to the support unit 200 arranged to face the gas supply unit 400.

According to one or more example embodiments, and briefly describing the process of generating the plasma PS, a process gas is supplied from the gas supply source 500 outside the process chamber 100 to the inner space 100S using the gas supply unit 400, and the process gas is converted into plasma PS by power generated by the power supply unit 600. Accordingly, the plasma PS is sprayed to the substrate WF on the support unit 200 arranged under the inner space 100S.

The plasma PS may include, but is not limited to, ions and/or radicals (hereinafter, collectively referred to as ions) of process gas and may serve as etching plasma PS for etching a film to be etched formed on the substrate WF. The gas supply unit 400 may form a plasma sheath having a uniform density on the upper portion of the substrate WF by inducing the ions to be distributed at a uniform density in the upper space of the substrate WF. Accordingly, a uniform etching process may be performed on the entire surface of the substrate WF.

In addition to the substrate WF, the top surface of the edge ring 220 may be partly exposed to the plasma PS. Accordingly, a coating layer 240 may be formed to protect the top surface of the edge ring 220 from the plasma PS. That is, the coating layer 240 is not a component derived from a process gas in the dry etching process and is intentionally formed in advance of the dry etching process. In order to perform a protective function, the thickness of the coating layer 240 may be selected in a range of about 100 nm to about 1 mm, but not one or more example embodiments are not limited thereto.

In one or more example embodiments, the coating layer 240 may be formed of a single layer of a polymer including a fluorocarbon-based material. Specifically, the coating layer 240 may be, but is not limited to, one selected from polytetrafluoroethylene (PTFE), polyvinylidene fluoride (PVDF), poly(vinylidene fluoride-trifluoroethylene) (PVDF-TrFE), perfluoroalkoxy alkane (PFA), and polychlorotrifluoroethylene (PCTFE). The coating layer 240 formed of such a material may chemically protect the edge ring 220 from the plasma PS.

In one or more example embodiments, the coating layer 240 may be formed of a single layer of a polymer including a phenyl ring or cyclic carbon. Specifically, the coating layer 240 may be, but is not limited to, one selected from polyetherimide (PEI), polybenzimidazole (PBI), and polydicyclopentadiene (pDCPD). The coating layer 240 formed of such a material may physically protect the edge ring 220 from the plasma PS.

In one or more example embodiments, the coating layer 240 may be formed of a single layer of ceramic including, but not limited to, a silicon nitride-based material. Specifically, the coating layer 240 may be, but is not limited to, one selected from silicon nitride (SiN), silicon oxynitride (SiON), and silicon carbonitride (SiCN). The coating layer 240 formed of such a material may reduce the relative etch rate of the edge ring 220 due to the plasma PS. Detailed descriptions of one or more example embodiments thereof will be further described below.

A temperature control means for maintaining a constant temperature of the substrate WF and the inner space 100S of the process chamber 100 during the plasma etching process for the substrate WF, and an exhaust means for discharging reaction byproducts of the etching process or residual process gas, in addition to the components described above, may be further arranged on a dry etching apparatus 10 according to one or more example embodiments.

Moreover, the substrate WF to be processed by the dry etching apparatus 10 may have an active surface, on which a semiconductor device is formed, and an inactive surface opposite the active surface and contacting the support unit 200. The active surface may correspond to a front-side surface of the substrate WF, and the inactive surface may correspond to a back-side surface of the substrate WF.

In general, a dry etching process using plasma PS anisotropically etches a film to be etched on the substrate WF, or the substrate WF itself, by using plasma, which is generated as the process gas is injected into the inner space 100S of the process chamber 100 through the gas supply unit 400. However, the plasma PS etches not only the material film to be etched on the substrate WF, or the substrate WF itself, but the plasma PS also etches the edge ring 220 of the dry etching apparatus 10, resulting in unwanted overetching.

In addition, in the plasma etching process of the substrate WF, a process gas used in a low temperature or cryogenic environment in which the temperature of the substrate is about 0° C. or less may include, but is not limited to, a hydrogen gas (H₂). Accordingly, any polymer protective layer naturally generated due to etching by-products on the edge ring 220 cannot be formed to a sufficient thickness to protect the edge ring 220. As described above with reference to one or more example embodiments, the process gas used in a low temperature or cryogenic environment may be determined according to the type of the film to be etched. Accordingly, it is substantially difficult to change the composition of the process gas to arbitrarily control the thickness of the polymer protective layer naturally formed on the edge ring 220.

Thus, one or more example embodiments comprise a method of intentionally forming the coating layer 240 in advance on the edge ring 220. Under suitable conditions (e.g., the constituent material of the coating layer, the thickness of the coating layer), according to one or more example embodiments, the coating layer 240 formed in advance on the edge ring 220 may sufficiently protect the edge ring 220 from the plasma PS.

According to one or more example embodiments, the coating layer 240 may also be applied to other components that make up the dry etching apparatus 10 and that may be exposed to plasma (PS) (including, but not limited to, a cover ring, a top electrode, a bottom electrode, a liner, a baffle, etc.) as well as the edge ring 220.

As explained above, the dry etching apparatus 10 according to one or more example embodiments may effectively address the problem of the upper surface of the edge ring 220 being damaged by the plasma PS by intentionally forming the coating layer 240 in advance on the edge ring 220. Accordingly, the lifespan of the edge ring 220 may be increased, and the period for performing maintenance on the dry etching apparatus 10 may be increased. Further, according to one or more example embodiments, the reliability and productivity of the dry etching apparatus 10 may be increased.

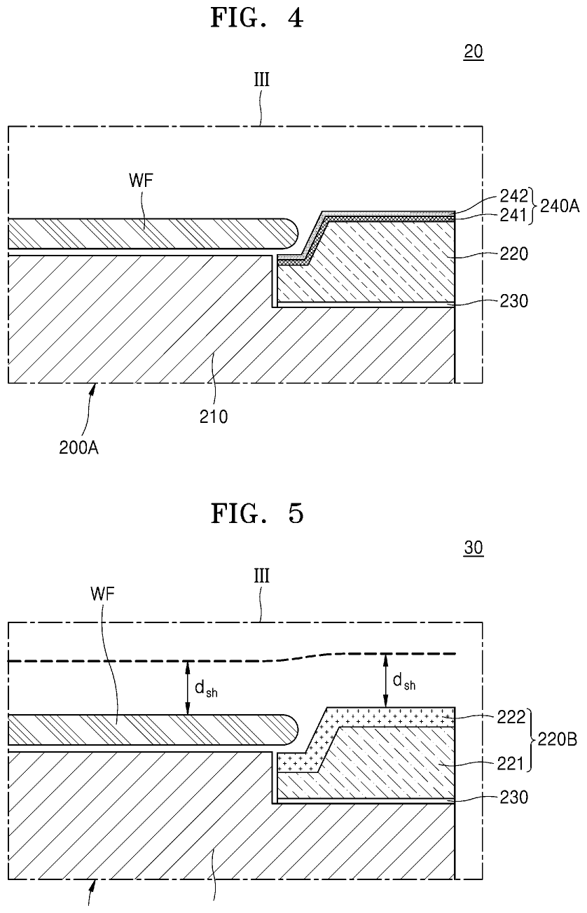

FIGS. 4 and 5 are cross-sectional views each illustrating a portion of a dry etching apparatus according to one or more example embodiments.

Some components constituting the dry etching apparatuses 20 and 30 described below and some materials constituting the components are substantially the same as, or similar to, those described above with reference to one or more example embodiments shown in FIGS. 1, 2 and 3. Accordingly, the description of one or more example embodiments below will focus on differences from the dry etching apparatus 10 described above.

For convenience of description, in the case of the dry etching apparatuses 20 and 30, the description will be focused on the enlarged cross-sectional view of region III of one or more example embodiments shown in FIG. 2.

FIG. 4 shows one or more example embodiments wherein the dry etching apparatus 20 in which a double-layered coating layer 240A is formed to protect the top surface of the edge ring 220 in a support unit 200A.

In the dry etching apparatus 20 of one or more example embodiments, a double-layered coating layer 240A, sequentially including the first coating layer 241 and the second coating layer 242, may be formed on the top surface of the edge ring 220.

Specifically, the coating layer 240A may include, but is not limited to, a double layer of different polymers. In one or more example embodiments, the first coating layer 241 may include, but is not limited to, a first polymer including a fluorocarbon-based material, and the second coating layer 242 may include, but is not limited to, a second polymer including a phenyl ring or cyclic carbon. In one or more example embodiments, the first coating layer 241 may include, but is not limited to, a second polymer including a phenyl ring or cyclic carbon, and the second coating layer 242 may include, but is not limited to, a first polymer including a fluorocarbon-based material.

The first polymer may be, but is not limited to, one selected from polytetrafluoroethylene (PTFE), polyvinylidene fluoride (PVDF), poly(vinylidene fluoride-trifluoroethylene) (PVDF-TrFE), perfluoroalkoxy alkane (PFA), and polychlorotrifluoroethylene (PCTFE). Such a material may chemically protect the edge ring 220 from plasma PS (see FIG. 1).

The second polymer may include, but is not limited to, a single layer of a polymer including a phenyl ring or cyclic carbon. Specifically, the coating layer 240 may be one selected from polyetherimide (PEI), polybenzimidazole (PBI), and polydicyclopentadiene (pDCPD). Such a material may physically protect the edge ring 220 from plasma PS (see FIG. 1).

In the dry etching apparatus 20 of one or more example embodiments, the coating layer 240A may physically and chemically protect the edge ring 220 from plasma PS (see FIG. 1) during the dry etching process.

FIG. 5 shows one or more example embodiments including a dry etching apparatus 30 having an edge ring 220B including a lower ring 221 and an upper ring 222 on the lower ring 221 in the support unit 200B.

The dry etching apparatus 30 of one or more example embodiments may include an edge ring 220B comprising a lower ring 221 attached to the electrostatic chuck 210 using an adhesive gel pad 230, wherein the lower ring 221 is not exposed to plasma PS (refer to FIG. 1), and an upper ring 222 disposed on the lower ring 221, wherein the upper ring 222 is exposed to plasma PS (refer to FIG. 1).

The lower ring 221 may include, but is not limited to, one selected from among silicon, silicon carbide, silicon nitride, silicon oxide, and aluminum oxide.

In one or more example embodiments, the upper ring 222 may include, but is not limited to, a polymer including a fluorocarbon-based material, and a polymer including a phenyl ring or cyclic carbon. Specifically, the upper ring 222 may be, but is not limited to, any one selected from polytetrafluoroethylene (PTFE), polyvinylidene fluoride (PVDF), poly (vinylidene fluoride-trifluoroethylene) (PVDF-TrFE), perfluoroalkoxy alkane (PFA), and polychlorotrifluoroethylene (PCTFE) or any one selected from polyetherimide (PEI), polybenzimidazole (PBI), and polydicyclopentadiene (pDCPD).

In one or more example embodiments, the upper ring 222 may include, but is not limited to, a ceramic including a silicon nitride-based material. Specifically, the upper ring 222 may be, but is not limited to, one selected from silicon nitride (SiN), silicon oxynitride (SiON), and silicon carbonitride (SiCN). The upper ring 222 formed of such a material may reduce the relative etch rate of the upper ring 222 from the plasma PS (see FIG. 1).

The upper ring 222 may be directly exposed to the plasma PS (refer to FIG. 1). Accordingly, the upper ring 222 may include, but is not limited to, a material having physical and chemical resistance from the plasma PS (refer to FIG. 1). That is, the upper ring 222 may protect the lower ring 221 during the dry etching process. In order to perform a protective function, according to one or more example embodiments, the thickness of the upper ring 222 may be selected in a range between about 1 mm and about 50% of the total thickness of the edge ring 220B, but is not limited thereto.

In addition, in the dry etching apparatus 30 of one or more example embodiments, the type of material constituting the lower ring 221 may be determined depending on the type of material constituting the upper ring 222. This is because the overall dielectric constant of the edge ring 220B is determined according to each material constituting the upper ring 222 and the lower ring 221.

The dielectric constant may be provided to satisfy a condition for constantly maintaining the distance dₛₕ to the interface (shown by a dotted line) of the sheath of the plasma PS (refer to FIG. 1) formed on the substrate WF and the edge ring 220B in the inner space (refer to 100S of FIG. 1) of the process chamber (refer to 100 of FIG. 1). If the distance dₛₕ is not maintained constant, excessive etching may be performed near the edge of the substrate WF. Therefore, in order to appropriately adjust the dielectric constant of the edge ring 220B, the material constituting the lower ring 221 and the upper ring 222 may be appropriately selected.

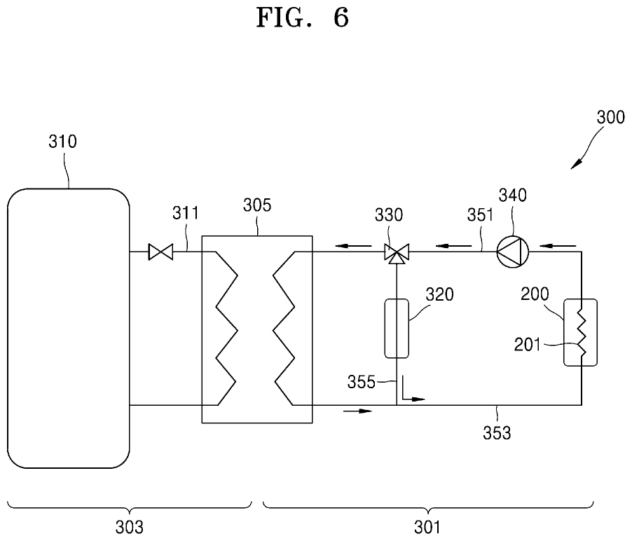

FIG. 6 is a schematic diagram of a cooling unit 300 included in a dry etching apparatus according to one or more example embodiments.

Referring to FIG. 6, the cooling unit 300 may include a cooling fluid cycle 301 during which a cooling fluid circulates and a refrigerant cycle 303 in which a refrigerant circulates.

The cooling fluid cycle 301 and the refrigerant cycle 303 may be connected through a heat exchanger 305. The heat exchanger 305 may perform heat exchange between the refrigerant and the cooling fluid.

The cooling fluid cycle 301 may include a heater 320 configured to heat the cooling fluid and at least a portion of a heat exchanger 305 configured to cool the cooling fluid through heat exchange with a refrigerant. The support unit 200, the heat exchanger 305, and the heater 320 may be connected through a flow path through which a cooling fluid flows, and a pump 340 for circulating the cooling fluid may be mounted on the flow path.

The cooling fluid cycle 301 may include a three-way valve 330 for regulating the flow rate of the cooling fluid passing through the heat exchanger 305 and for regulating the flow rate of the cooling fluid passing through the heater 320. For example, the cooling unit 300 may be configured to adjust the temperature of the cooling fluid supplied to the support unit 200 by at least one of adjusting the flow rate of the cooling fluid passing through the heat exchanger 305 and adjusting the flow rate of the cooling fluid passing through the heater 320 through the three-way valve 330. The cooling unit 300 may control the support unit 200 and the temperature of the substrate WF on the support unit 200 by supplying a mixed cooling fluid, in which the cooling fluid passing through the heat exchanger 305 and the cooling fluid passing through the heater 320 are mixed, to the support unit 200.

Specifically, the cooler 310 and the outlet of the cooling channel 201 may be connected by a first flow path 351. Further, the cooler 310 and the inlet of the cooling channel 201 of the support unit 200 may be connected by a second flow path 353. The heater 320 may be installed in a bypass flow path 355 connecting the first flow path 351 to the second flow path 353. The bypass flow path 355 may directly connect the first flow path 351 to the second flow path 353 without passing through the heat exchanger 305. The bypass flow path 355 may allow all or part of the cooling fluid to be supplied to the support unit 200 without passing through the heat exchanger 305. The three-way valve 330 is arranged at a point where the first flow path 351 and the bypass flow path 355 intersect. The three-way valve 330 may control the flow rate of the cooling fluid passing through the heat exchanger 305 and may control the flow rate of the cooling fluid passing through the heater 320. According to one or more example embodiments, the temperature of the cooling fluid supplied to the support unit 200 may be determined by mixing the cooling fluid passing through the heat exchanger 305 and the cooling fluid passing through the heater 320.

The refrigerant cycle 303 may include a cooler 310 and a refrigerant flow path 311 through which the refrigerant circulates. The cooler 310 may include, but is not limited to, various devices for cooling the refrigerant flowing along the refrigerant flow path 311. For example, the cooler 310 may include, but is not limited to, a condenser, a compressor, an expansion valve, etc. of the refrigerant cycle 303. The heat exchanger 305 may perform heat-exchange between the refrigerant supplied from the refrigerant flow path 311, through which the refrigerant flows, and the cooling fluid supplied through the first flow path 351, to thereby cool the cooling fluid.

In the dry etching apparatus 10 according to one or more example embodiments, because the temperature of the cooling fluid may be quickly adjusted by controlling the flow rate passing through the heat exchanger 305 and by controlling the flow rate passing through the heater 320 using the three-way valve 330, a temperature suitable for performing a low temperature or cryogenic etching process may be quickly provided to the substrate WF.

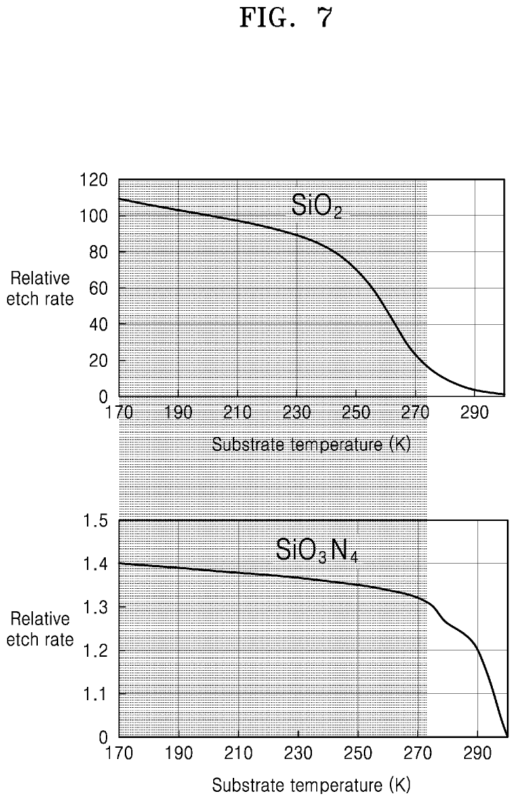

FIG. 7 is a graph illustrating a relative etch rate according to materials in a dry etching apparatus according to one or more example embodiments.

Referring to FIG. 7, according to one or more example embodiments, experimental examples of different materials show that, in a low temperature or cryogenic environment below about 0° C. (hatched portions in the graphs shown in FIG. 7), when the coating layer 240 (refer to FIG. 2) is made of silicon oxynitride (SiO₃N₄) (lower graph of FIG. 7), the relative etch rate is reduced to about 1/50 compared to when the coating layer 240 is made of silicon oxide (SiO₂) (upper graph of FIG. 7).

For example, the relative etch rate of silicon oxide (upper graph of FIG. 7) is about 110 at about −100° C. (corresponding to the 173K point in the graph), and the relative etch rate of silicon oxynitride (lower graph of FIG. 7) is about 1.4. That is, according to one or more example embodiments, when silicon oxynitride having a relatively low etch rate in a low temperature or cryogenic environment is used as the coating layer 240 (see FIG. 2), the edge ring 220 (see FIG. 2) may be effectively protected.

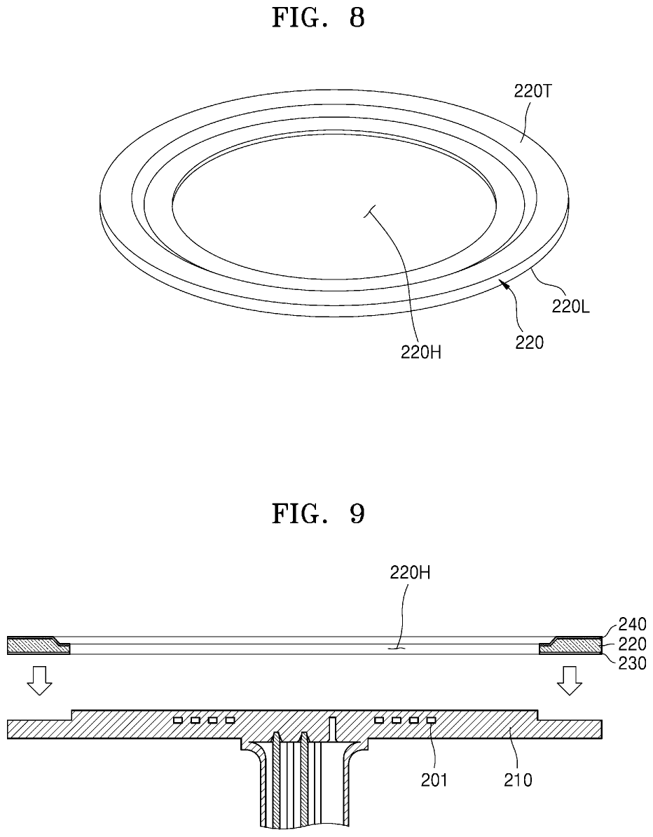

FIG. 8 is a perspective view of an edge ring included in a dry etching apparatus according to one or more example embodiments, and FIG. 9 is a cross-sectional view illustrating a process in which the edge ring of FIG. 8 is attached to an electrostatic chuck according to one or more example embodiments.

Referring to FIGS. 8 and 9 together, according to one or more example embodiments, an edge ring 220 and a state in which the edge ring 220 is being attached to the electrostatic chuck 210 are illustrated.

The edge ring 220 may be used as a part of the support unit 200 (see FIG. 1) in the dry etching apparatus 10 (see FIG. 1), may have a lower surface 220L and an upper surface 220T opposite to the lower surface 220L, and may be formed of an annular body in which an empty space 220H is formed in the center of the annular body.

First, a coating layer 240, which may be polymer-based or ceramic-based, but is not limited thereto, is formed on the upper surface 220T of the edge ring 220. Because the material constituting the coating layer 240 may be the same as one or more example embodiments described above, detailed descriptions thereof are omitted.

As described above, according to one or more example embodiments, because the coating layer 240 is formed in advance on the upper surface 220T of the edge ring 220, during the manufacturing process of the edge ring 220, the coating layer 240 may be formed at a different time from that of a polymer, which is a by-product generated in the dry etching process, and the coating layer 240 may have a different homogeneity of film quality.

Next, the adhesive gel pad 230 may be attached to the lower surface 220L of the edge ring 220, and the edge ring 220 may be bonded to the electrostatic chuck 210 using the adhesive gel pad 230. That is, the electrostatic chuck 210 and the edge ring 220 may be bonded to each other using the adhesive gel pad 230 and without using a fastening member such as a bolt. The adhesive gel pad 230 may include, but is not limited to, a material having adhesive properties and thermal conductivity.

In this manner, the dry etching apparatus 10 according to one or more example embodiments may increase the lifespan of the edge ring 220 and may increase the maintenance interval for the dry etching apparatus 10 (refer to FIG. 1) by intentionally forming the coating layer 240 on the edge ring 220 in advance. Accordingly, one or more example embodiments may increase the reliability and productivity of the dry etching apparatus 10 (refer to FIG. 1).

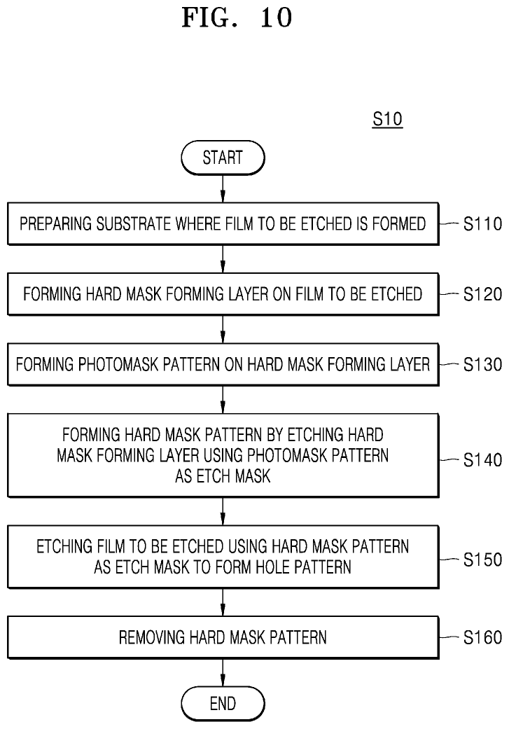

FIG. 10 is a flowchart illustrating a pattern forming process for forming a semiconductor device using a dry etching apparatus according to one or more example embodiments.

Referring to FIG. 10, according to one or more example embodiments, the pattern forming process S10 of the semiconductor device may include a process sequence comprising operations S110, S120, S130, S140, S150 and S160.

In one or more example embodiments, a specific process sequence may be different from the example sequence described with reference to one or more example embodiments shown in FIG. 10. For example, according to one or more example embodiments, two of the processes described in succession with reference to one or more example embodiments shown in FIG. 10, may be performed substantially simultaneously, or may be performed in an order opposite to, or in an order different from, the order described with reference to FIG. 10.

The pattern forming process (S10) of the semiconductor device according to one or more example embodiments may include a first operation of preparing a substrate where a film to be etched is formed (S110); a second operation of forming a hard mask forming layer on the film to be etched (S120); a third operation of forming a photomask pattern on the hard mask forming layer (S130); a fourth operation of forming a hard mask pattern by etching the hard mask forming layer using the photomask pattern as an etch mask (S140); a fifth operation of etching the film to be etched using the hard mask pattern as an etch mask to form a hole pattern (S150); and a sixth operation of removing the hard mask pattern (S160).

Because miniaturization, multifunctionality, and high performance of electronic products are needed, a high-capacity semiconductor device is needed, and an increased integration density is needed to provide a high-capacity semiconductor device. As described above, as the integration density of semiconductor devices increases, design rules for components of semiconductor devices are decreasing, and a pattern having a high aspect ratio is needed. During the manufacturing process of a highly reduced semiconductor device, defects in an etch profile, etc. may occur, making it increasingly difficult to form a pattern having a high aspect ratio.

The pattern forming process (S10) of the semiconductor device according to one or more example embodiments may improve a mask clogging defect that occurs at the entrance of the hard mask and may protect an edge ring using the coating layer 240 during the process of performing plasma dry etching to form a pattern of high aspect ratio on the film to be etched.

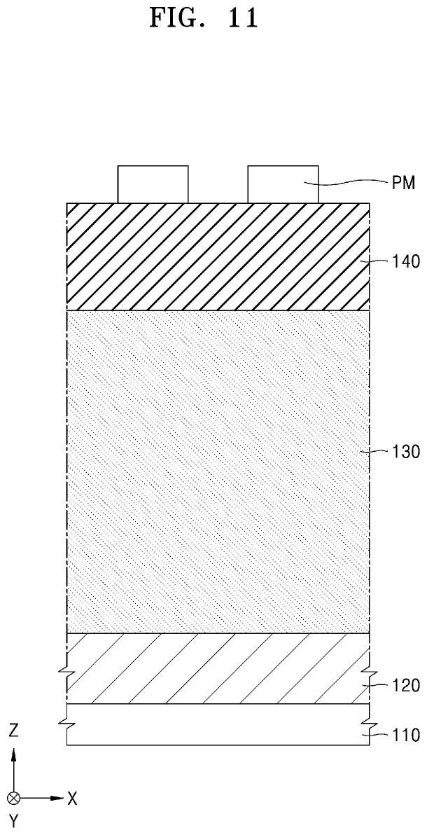

The technical characteristics of each of the operations S110, S120, S130, S140, S150 and S160 will be described below in detail with reference to FIGS. 11, 12, 13, 14 and 15.

FIGS. 11, 12, 13, 14 and 15 are cross-sectional views shown at each process sequence of the pattern forming process of the semiconductor device of FIG. 10 according to one or more example embodiments.

Referring to FIG. 11, according to one or more example embodiments, a lower film to be etched 120, an upper film to be etched 130, a hard mask forming layer 140, and a photomask pattern PM may be sequentially formed on the semiconductor substrate 110.

The semiconductor substrate 110 may include, but is not limited to, a semiconductor material, for example, silicon (Si). Alternatively, the semiconductor substrate 110 may include, but is not limited to, a semiconductor element material, such as germanium (Ge), or a compound semiconductor material, such as silicon carbide (SiC), gallium arsenide (GaAs), indium arsenide (InAs), and indium phosphide (InP). In one or more example embodiments, the semiconductor substrate 110 may have a silicon-on-insulator (SOI) structure. The semiconductor substrate 110 may include, but is not limited to including, a conductive region, such as an impurity-doped well or an impurity-doped structure.

A semiconductor device may be positioned on the semiconductor substrate 110. The semiconductor device may include, but is not limited to, a memory device and/or a logic device. In addition, the semiconductor device may include, but is not limited to, a plurality of individual devices of various types. The plurality of individual devices may include, but are not limited to, at least one of a transistor, a diode, a capacitor, or a resistor.

A lower film to be etched 120 and an upper film to be etched 130 may be formed on the semiconductor substrate 110. In one or more example embodiments, the lower film to be etched 120 and the upper film to be etched 130 may be formed of different insulating materials. For example, the lower film to be etched 120 and the upper film to be etched 130 may be formed by stacking silicon oxide and silicon nitride. The lower film to be etched 120 and the upper film to be etched 130 may be an inter layer dielectric (ILD), an inter metal dielectric (IMD), or a memory semiconductor device depending on the formation method and the uses of the lower film to be etched 120 and the upper film to be etched 130.

The types and uses of the lower film to be etched 120 and the upper film to be etched 130 are not limited to the one or more example embodiments described above. In one or more example embodiments, the lower film to be etched 120 and the upper film to be etched 130 may be formed of conductive materials. The lower film to be etched 120 and the upper film to be etched 130 may include, but are not limited to, tungsten (W), a tungsten alloy, copper (Cu), or a copper alloy. Alternatively, the lower film to be etched 120 and the upper film to be etched 130 may include, but are not limited to, aluminum (Al), titanium (Ti), tantalum (Ta), palladium (Pd), platinum (Pt), molybdenum (Mo), metal silicide, or a combination thereof.

Next, a hard mask forming layer 140 may be formed on the upper film to be etched 130. The hard mask forming layer 140 may be selected from, but is not limited to, materials having a high etch selectivity in a relationship with the upper film to be etched 130. In general, various silicon-based materials and/or materials in which impurities are added to silicon-based materials may be used as the hard mask forming layer 140. In one or more example embodiments, the hard mask forming layer 140 may include, but is not limited to, a material composed of silicon boride and silicon (Si), but one or more example embodiments are not limited thereto.

Next, a photo-resist may be applied on the hard mask forming layer 140, and the photo-resist may be patterned through an exposure and development process to form a photomask pattern PM. Regions to be etched of the lower film to be etched 120 and the upper film to be etched 130 may be defined by the photomask pattern PM. In one or more example embodiments, an anti-reflective coating (ARC) film may be formed between the hard mask forming layer 140 and a photo-resist.

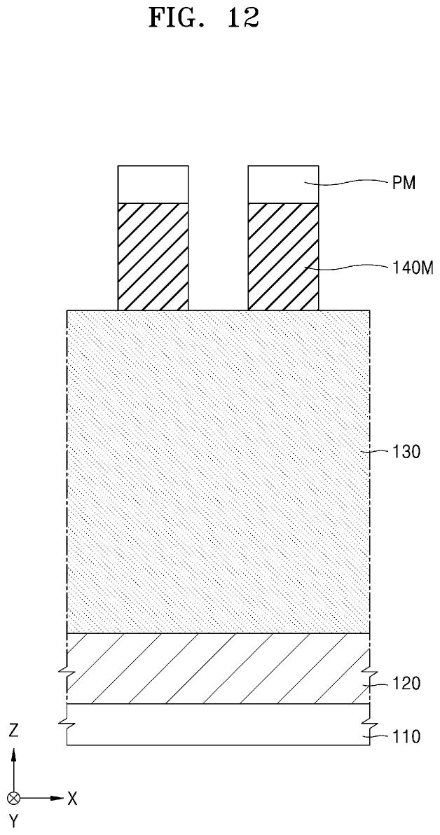

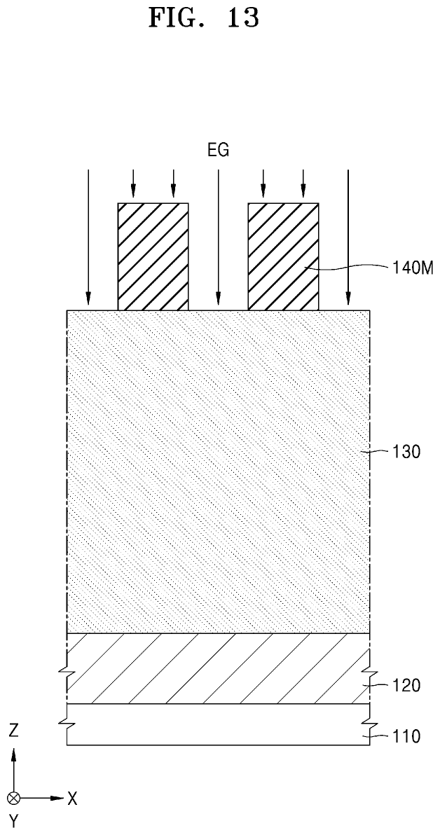

Referring to FIG. 12, according to one or more example embodiments, the hard mask forming layer 140 (refer to FIG. 11) may be etched using the photomask pattern PM as an etch mask to form a hard mask pattern 140M.

The etching process may be, but is not limited to, a dry etching process using plasma. Specifically, the plasma may be injected in a direction in which the semiconductor substrate 110 is located, and the plasma is composed of ions and/or radicals of the process gas and may serve as an etching plasma for etching the hard mask forming layer 140 (refer to FIG. 2) formed on the semiconductor substrate 110.

Referring to FIG. 13, according to one or more example embodiments, the photomask pattern PM (refer to FIG. 12) may be removed by ashing and strip processes.

Subsequently, the upper film to be etched 130 may be etched using the hard mask pattern 140M as an etch mask and using a process gas including, but not limited to, a hydrogen gas (H₂) and a fluorocarbon gas (CₓF_{y}) as an etching gas (EG).

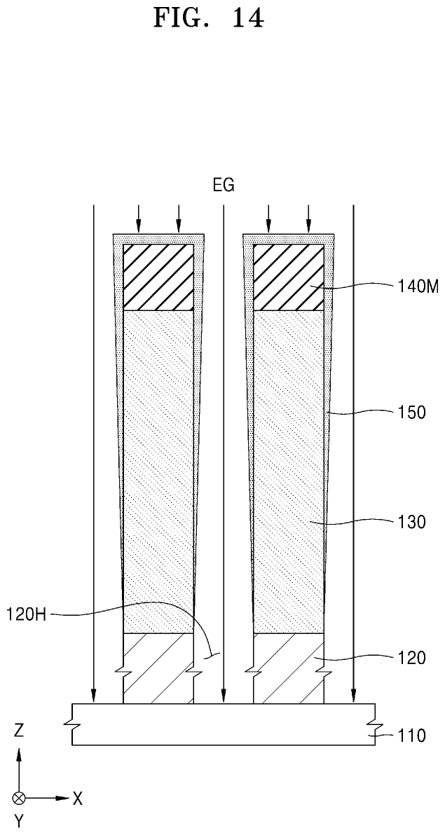

Referring to FIG. 14, according to one or more example embodiments, a plurality of hole patterns 120H may be formed on the lower film to be etched 120 by etching the lower film to be etched 120 using the hard mask pattern 140M and the upper film to be etched 130 as an etch mask.

In one or more example embodiments, a plurality of hole patterns 120H may be formed to penetrate the lower film to be etched 120 and, a portion of the top surface of the semiconductor substrate 110 may be exposed. It is illustrated in FIG. 14 that, according to one or more example embodiments, the thickness of the lower film to be etched 120 is small for convenience of description, but one or more example embodiments are not limited thereto.

The process gas used in a low temperature or cryogenic environment in which the temperature of the semiconductor substrate 110 may be about 0° C. or less includes, but is not limited to, a hydrogen gas (H₂). Accordingly, even if the etching by-product 150 is formed on an inner wall of the plurality of hole patterns (120H), a mask clogging defect that blocks the entrance of the hard mask pattern 140M may not occur.

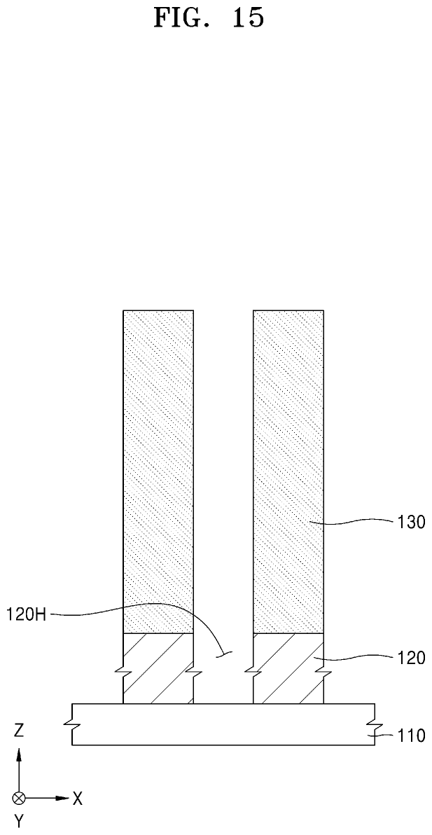

Referring to FIG. 15, according to one or more example embodiments, a process of forming a pattern having a high aspect ratio, such as a plurality of hole patterns 120H, on the lower film to be etched 120 and the upper film to be etched 130 may be completed by removing the hard mask pattern (refer to 140M of FIG. 14).

Both the hard mask pattern 140M (refer to FIG. 14) and the etching by-product 150 (refer to FIG. 14) may be removed through a wet etching process. The wet etching process may be performed using a wet etching solution, such as hydrofluoric acid or a buffered oxide etchant (BOE) solution. The wet etching process may comprise a process that minimizes the effects on the lower film to be etched 120, the upper film to be etched 130, and the plurality of hole patterns 120H.

As such, the dry etching apparatus 10 (refer to FIG. 1) according to one or more example embodiments may form a plurality of hole patterns 120H having a high aspect ratio on the semiconductor substrate 110 and may effectively address a problem that the upper surface of the edge ring 220 (refer to FIG. 1) is damaged in a low temperature or cryogenic environment.

Accordingly, one or more example embodiments may increase the lifespan of the edge ring 220 (refer to FIG. 1), and may increase a maintenance interval for the dry etching apparatus 10 (refer to FIG. 1). Further, one or more example embodiments may increase the reliability and productivity of the dry etching apparatus 10 (refer to FIG. 1).

While one or more example embodiments have been particularly shown and described above, it will be apparent to those skilled in the art that various changes in form and details may be made to one or more example embodiments without departing from the spirit and scope of the following claims.

1. A dry etching apparatus comprising:
a process chamber;
a support provided in the process chamber and configured to support a substrate;
a gas supply configured to supply a process gas comprising a hydrogen gas (H₂) and a fluorocarbon gas (CₓF_{y}) into the process chamber;
a plasma source configured to generate plasma using the process gas in the process chamber,
wherein the support comprises:
an electrostatic chuck on which the substrate is disposed;
an edge ring provided along a circumference of the electrostatic chuck and supporting an edge region of the substrate;
an adhesive gel pad provided between the electrostatic chuck and the edge ring; and
a coating layer formed only on a surface of the edge ring, which is exposed to the plasma.

2. The dry etching apparatus of claim 1, wherein the coating layer comprises a single layer of a polymer comprising a fluorocarbon-based material.

3. The dry etching apparatus of claim 2, wherein the coating layer comprises one of polytetrafluoroethylene (PTFE), polyvinylidene fluoride (PVDF), poly(vinylidene fluoride-trifluoroethylene) (PVDF-TrFE), perfluoroalkoxy alkane (PFA), or polychlorotrifluoroethylene (PCTFE).

4. The dry etching apparatus of claim 1, wherein the coating layer comprises a single layer of a polymer comprising a phenyl ring or cyclic carbon.

5. The dry etching apparatus of claim 4, wherein the coating layer comprises one of polyetherimide (PEI), polybenzimidazole (PBI), or polydicyclopentadiene (pDCPD).

6. The dry etching apparatus of claim 1, wherein the coating layer comprises first layer comprising a first polymer and a second layer comprising a second polymer that is different than the first polymer,
wherein the first polymer comprises a fluorocarbon-based material, and
wherein the second polymer comprises a phenyl ring or cyclic carbon.

7. The dry etching apparatus of claim 1, wherein the coating layer comprises a single layer of ceramic comprising a silicon nitride-based material.

8. The dry etching apparatus of claim 1, wherein the edge ring comprises one of silicon, silicon carbide, silicon nitride, silicon oxide, or aluminum oxide.

9. The dry etching apparatus of claim 1, wherein a thickness of the coating layer is between about 100 nm to about 1 mm.

10. The dry etching apparatus of claim 1, further comprising a cooling device configured to cool the support to maintain a temperature of the substrate in the process chamber at about 0° C. or less.

11. A dry etching apparatus comprising:
a process chamber;
a support configured to support a substrate in the process chamber;
a gas supply configured to supply a process gas comprising a hydrogen gas (H₂) and a fluorocarbon gas (CₓF_{y}) into the process chamber;
a plasma source configured to generate plasma using the process gas in the process chamber,
wherein the support comprises:
an electrostatic chuck on which the substrate is disposed;
an edge ring provided along a circumference of the electrostatic chuck and supporting an edge region of the substrate; and
an adhesive gel pad between the electrostatic chuck and the edge ring, and
wherein the edge ring comprises:
a lower ring attached to the electrostatic chuck and configured to not be exposed to the plasma; and
an upper ring provided on the lower ring and is configured to be exposed to the plasma.

12. The dry etching apparatus of claim 11, wherein the upper ring comprises:
a first polymer comprising at least a fluorocarbon-based material; or
a second polymer comprising a phenyl ring or cyclic carbon.

13. The dry etching apparatus of claim 11, wherein the upper ring comprises a ceramic comprising a silicon nitride-based material.

14. The dry etching apparatus of claim 11, wherein a thickness of the upper ring is between about 1 mm to about 50% of a total thickness of the edge ring.

15. The dry etching apparatus of claim 11, wherein the lower ring comprises materials determined according to materials comprising the upper ring, and
wherein the edge ring is configured such that an overall dielectric constant of the edge ring is configured to maintain a distance between an interface of a sheath of a plasma formed on the substrate and the edge ring in an inner space of the process chamber.

16. An edge ring comprising:
an annular body configured to be used in dry etching equipment where an etching process is performed in a low-temperature environment, the annular body having a lower surface and an upper surface facing the lower surface;
a thermally conductive adhesive gel pad adhered to the lower surface of the annular body; and
a coating layer provided on the upper surface of the annular body, and the coating layer comprising a material having etching resistance to a hydrogen gas (H₂) and a fluorocarbon gas (CₓF_{y}).

17. The edge ring of claim 16, wherein the coating layer comprises:
polytetrafluoroethylene (PTFE), polyvinylidene fluoride (PVDF), poly(vinylidene fluoride-trifluoroethylene) (PVDF-TrFE), perfluoroalkoxy alkane (PFA), or polychlorotrifluoroethylene (PCTFE); or
a single layer of a polymer comprising polyetherimide (PEI), polybenzimidazole (PBI), or polydicyclopentadiene (pDCPD).

18. The edge ring of claim 16, wherein the coating layer comprises a first layer comprising a first polymer and a second layer comprising a second polymer that is different than the first polymer,
wherein the first a fluorocarbon-based material, and
wherein the second polymer comprises a phenyl ring or cyclic carbon.

19. The edge ring of claim 16, wherein the coating layer comprises a single layer of ceramic comprising a silicon nitride-based material.

20. The edge ring of claim 16, further comprising a cooling device configured to cool the support to maintain a temperature of a substrate on a portion of the edge ring at about 0° C. or less,
wherein a thickness of the coating layer is between about 100 nm to about 1 mm, and
wherein the edge ring comprises one of silicon, silicon carbide, silicon nitride, silicon oxide, and aluminum oxide.

21.-25. (canceled)
